(19) United States
(12) Patent Application Publication
(10) Pub. No.: US 2026/0190801 A1
(43) Pub. Date: Jul. 2, 2026

(54) Display Apparatus

(71) Applicant: LG Display Co., Ltd., Seoul (KR)

(72) Inventors: Kyuhwan Lee, Paju-si (KR); InGoo Lee, Paju-si (KR); GiBin Kim, Paju-si (KR); SeHong Park, Paju-si (KR)

(21) Appl. No.: 19/334,186

(22) Filed: Sep. 19, 2025

(30) Foreign Application Priority Data
Dec. 26, 2024 (KR) 10-2024-0197492

(51) Int. Cl. H10K 59/80; H10K 59/124

(52) U.S. Cl. CPC H10K 59/878; H10K 59/124; H10K 59/879

(57) ABSTRACT

A display apparatus comprises a substrate on which a plurality of subpixels are arranged; a first planarization layer disposed on the substrate; a second planarization layer disposed on the first planarization layer and having a different refractive index from the first planarization layer; and a sloped reflective portion disposed on the second planarization layer and arranged obliquely in a non-light emission area between the plurality of subpixels, which can reflect light emitted from a light emission area of one of the plurality of subpixels toward an adjacent subpixel toward the substrate, wherein the first planarization layer includes a first sloped portion arranged obliquely, and the first sloped portion partially overlaps the sloped reflective portion.

### CROSS-REFERENCE TO RELATED APPLICATIONS

This application claims the benefit of the Korean Patent Application No. 10-2024-0197492 filed on Dec. 26, 2024, which is hereby incorporated by reference as if fully set forth herein.

### BACKGROUND

### Field of the Invention

The present disclosure relates to a display apparatus for displaying an image.

### Discussion of the Related Art

With the advancement of information-oriented society, various requirements for display apparatuses for displaying an image are increasing. Therefore, various display apparatuses such as liquid crystal display apparatuses, plasma display apparatuses, organic light emitting display apparatuses, and quantum-dot light emitting display apparatuses and electroluminescent display apparatuses are being used recently.

In display apparatuses, organic light-emitting display apparatuses are self-emitting display apparatuses and do not require a separate backlight compared to liquid crystal display apparatuses, so they can be made thin and light, and have an advantage of low power consumption.

Recently, organic light emitting display apparatuses of a bottom emission type where reflective electrodes are disposed along grooves after the grooves are formed at boundary portions between subpixels are being developed for increasing the light extraction efficiency of light emitted from an emission layer of each of a plurality of subpixels. Since organic light emitting display apparatuses of the bottom emission type must emit light downward, the reflective electrodes around the light-emission area must be arranged at an angle. However, if an angle of inclination of the reflective electrodes with respect to a ground is too small, color mixing between subpixels may occur. Therefore, organic light emitting display apparatuses of the bottom emission type have limitations in improving a viewing angle.

### SUMMARY

An aspect of the present disclosure is directed to providing a display apparatus whose viewing angle can be improved.

Further, an aspect of the present disclosure is directed to providing a display apparatus in which the light extraction efficiency of light emitted from a light-emitting element layer can be improved.

Further, an aspect of the present disclosure is directed to providing a display apparatus in which the overall power consumption can be reduced through light extraction in a non-light emission area.

The problems to be solved by the present disclosure are not limited to those mentioned above, and other problems not mentioned will be apparent to one of ordinary skill in the art to which the technical spirits of the present disclosure belong from the following description.

A display apparatus comprising: a substrate on which a plurality of subpixels are arranged; a first planarization layer disposed on the substrate; a second planarization layer disposed on the first planarization layer and having a different refractive index from the first planarization layer; and a sloped reflective portion disposed on the second planarization layer and arranged obliquely in a non-light emission area between the plurality of subpixels, which can reflect light emitted from a light emission area of one of the plurality of subpixels toward an adjacent subpixel toward the substrate, wherein the first planarization layer includes a first sloped portion arranged obliquely, and the first sloped portion partially overlaps the sloped reflective portion.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view showing one pixel illustrated in FIG. 1.

FIG. 3 is a schematic cross-sectional view of the line I-I′ shown in FIG. 2.

FIG. 4 is a schematic cross-sectional view of the line II-II′ shown in FIG. 2.

FIG. 5 is an enlarged view of a part A shown in FIG. 3.

FIG. 6 is an enlarged view of a part B shown in FIG. 3.

FIG. 7 is a graph showing the viewing angle of a display apparatus according to one embodiment of the present disclosure and the viewing angle of a display apparatus according to a comparative example.

FIG. 8 is a schematic cross-sectional view of a display apparatus according to a second embodiment of the present disclosure, which is another example of FIG. 3.

FIG. 9 is a schematic cross-sectional view of a display apparatus according to a third embodiment of the present disclosure, which is another example of FIG. 5.

### DETAILED DESCRIPTION OF THE DISCLOSURE

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely one example, and thus, the present disclosure is not limited to the illustrated details. Like reference numerals refer to like elements throughout the present disclosure. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only-’ is used. The terms of a singular form may include plural forms unless referred to the contrary.

In construing an element, the element is construed as including an error range although there is no explicit description.

In describing a position relationship, for example, when a position relation between two parts is described as ‘on-’, ‘over-’, ‘under-’, or ‘next-’, one or more other parts may be disposed between the two parts unless ‘just’ or ‘direct’ is used.

In describing a temporal relationship, for example, when the temporal order is described as “after”, “subsequent”, “next”, and “before”, a case which is not continuous may be included, unless “just” or “direct” is used.

It will be understood that, although the terms “first”, “second”, etc. may be used herein to describe various elements, these elements should not be limited by these terms. These terms are only used to distinguish one element from another element. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

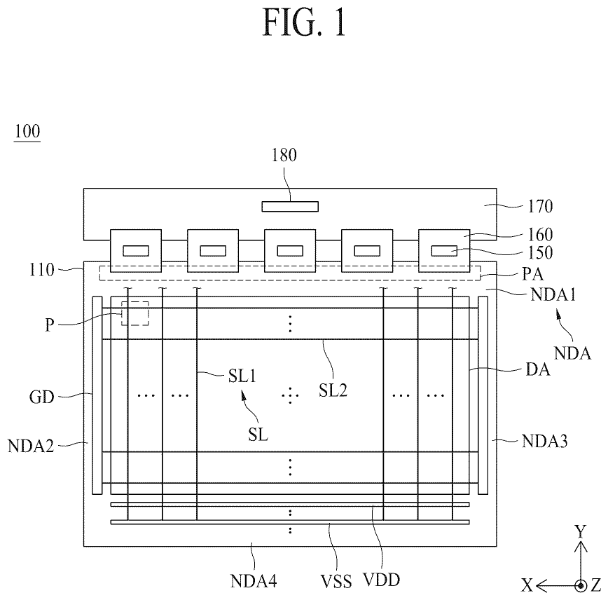

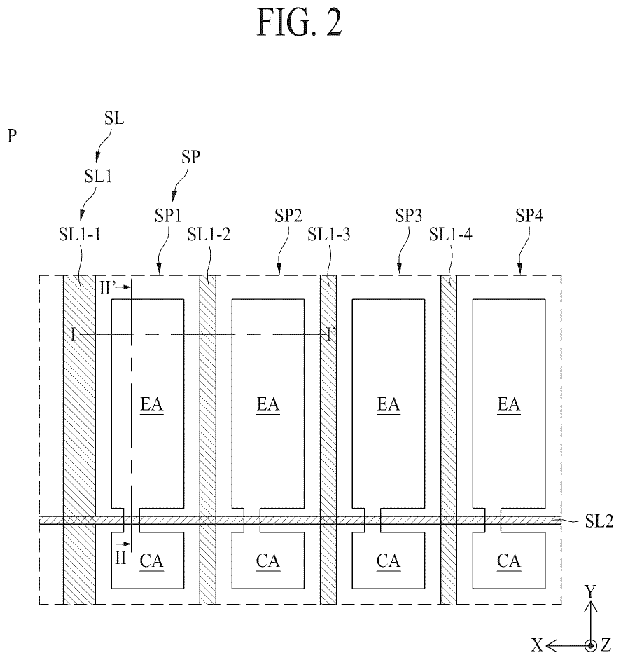

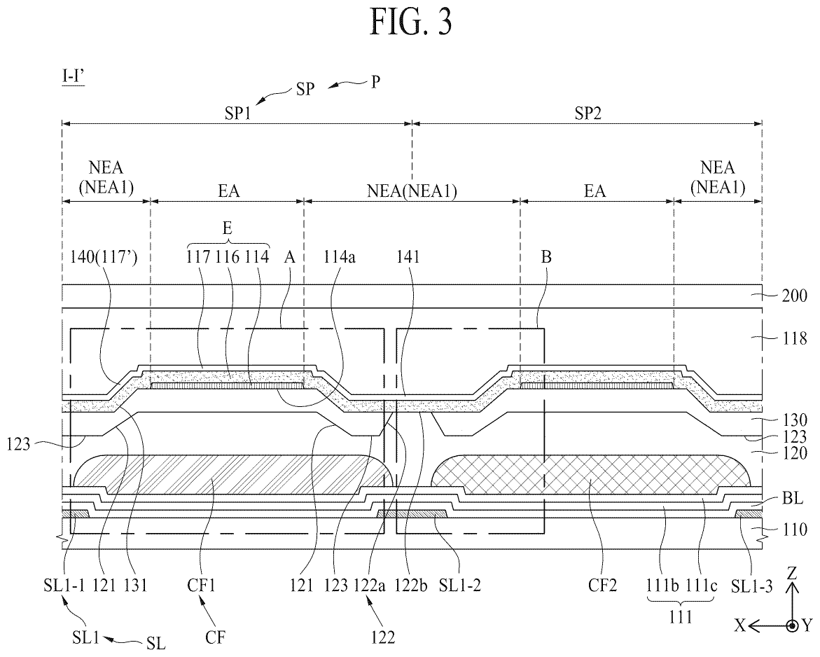

FIG. 1 is a schematic plan view of a display apparatus according to one embodiment of the present disclosure, FIG. 2 is a schematic plan view showing one pixel illustrated in FIG. 1, and FIG. 3 is a schematic cross-sectional view of the line I-I′ shown in FIG. 2.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a first line SL1 (e.g., data line). The second direction (X-axis direction) may be a direction parallel to a second line SL2 (e.g., gate line).

The following description will be based on that the display apparatus 100 according to one embodiment of the present disclosure is an organic light emitting display apparatus, but is not limited thereto. That is, the display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

Referring to FIG. 1, a display apparatus 100 according to one embodiment of the present disclosure may include a display panel having a gate driver GD. The display panel may include a substrate 110 and an opposing substrate 200 (shown in FIG. 3) bonded to each other.

The substrate 110 according to one example may include a display area DA in which a plurality of pixels P each of which having a plurality of subpixels SP are arranged, and a non-display area NDA around the display area DA (in other words, the display panel may include the display area DA and the non-display area NDA). The substrate 110 may further include lines SL arranged between the plurality of pixels P (or the plurality of sub-pixels SP).

Referring to FIG. 1, the display apparatus 100 according to one embodiment of the present disclosure may include a source drive integrated circuit (Hereinafter referred to as “source drive IC”) 150, a flexible film 160, a circuit board 170, and a timing control portion 180.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion of the substrate 110. The opposing substrate 200 may be an upper substrate, a second substrate, or an encapsulation substrate.

The gate driver GD supplies gate signals to the gate lines in accordance with the gate control signal input from the timing control portion 180. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

Referring to FIG. 1, the display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel power lines, and a plurality of pixels P. Each of the plurality of pixels P may include a plurality of sub-pixels SP that may be defined by gate lines and data lines. Each of the plurality of subpixels SP may include a light-emission area EA and a circuit area CA adjacent to the light-emission area EA, as shown in FIG. 2.

The light-emission area EA according to one example may be defined as the smallest unit area where actual light is emitted. The circuit area CA according to one example may be defined as an area in which a thin film transistor is provided for emitting light in the light-emission area EA. As illustrated in FIG. 2, the circuit area CA may be arranged adjacent to one side of the light-emission area EA. For example, the light-emission area EA and the circuit area CA may be arranged in the first direction (Y-axis direction) so as to be arranged parallel to a first line SL1. For example, the first line SL1 may be any one of a pixel power line, a common power line, a reference line, and a data line.

Meanwhile, as shown in FIG. 2, at least four subpixels SP arranged adjacently and configured to emit different colors among a plurality of subpixels SP constitute one pixel P (or unit pixel P). The one pixel P may include, but is not limited to, a red subpixel, a green subpixel, a blue subpixel, and a white subpixel. For example, the red subpixel may be a first subpixel SP1, the green subpixel may be a second subpixel SP2, the blue subpixel may be a third subpixel SP3, and the white subpixel may be a fourth subpixel SP4.

Each of the plurality of subpixels SP may include a thin film transistor and an organic light-emitting element connected to the thin film transistor. The subpixel may include a light-emitting layer (or organic light-emitting layer) interposed between an anode electrode and a reflective portion.

The light-emitting layer (or organic light-emitting layer) arranged in each of the plurality of subpixels SP can individually emit different color light or commonly emit white light. For example, when the light-emitting layer (or organic light-emitting layer) of each of the plurality of sub-pixels SP commonly emits white light, each of the red sub-pixel, the green sub-pixel, and the blue sub-pixel may include a color filter CF (or wavelength conversion member CF) that converts the white light into light of a different color. In this case, the white subpixel according to one example may not have a color filter. In a display apparatus 100 according to one embodiment of the present disclosure, an area provided with a red color filter CF1 (or a first color filter CF1) may be a red subpixel SP1, an area provided with a green color filter CF2 (or a second color filter CF2) may be a green subpixel SP2, an area provided with a blue color filter may be a blue subpixel SP3, and an area without the color filter may be a white subpixel SP4. As a result, the second color filter CF2 may be a color filter of a different color from the first color filter CF1.

Each of the plurality of subpixels SP supplies a predetermined current to the organic light emitting element in accordance with a data voltage of the data line when a gate signal is input from the gate line by using the thin film transistor. For this reason, the light emitting layer of each of the plurality of subpixels may emit light with a predetermined brightness in accordance with the predetermined current.

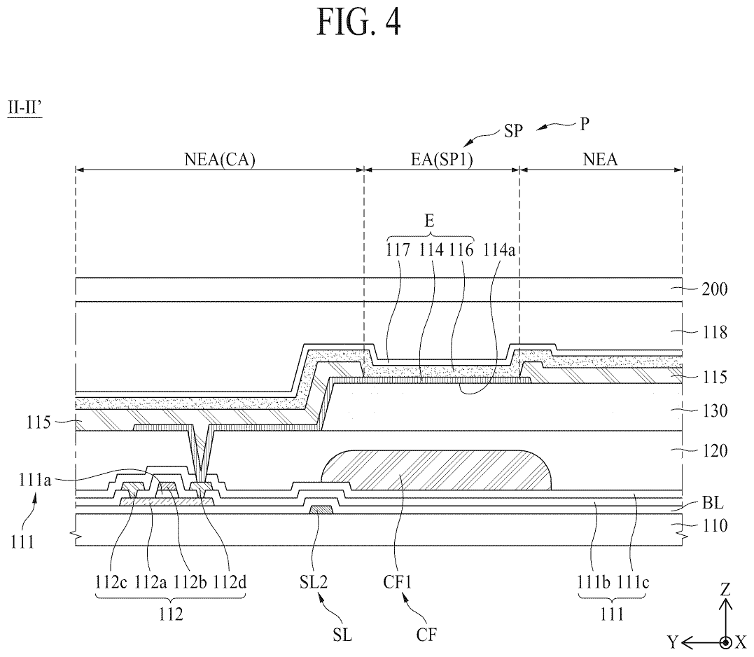

Meanwhile, each of the plurality of subpixels SP emitting different colors has the same shape and size as shown in FIG. 2 and is arranged with four subpixels spaced apart from each other. For example, it may include a first subpixel SP1, a second subpixel SP2, a third subpixel SP3, and a fourth subpixel SP4. However, it is not necessarily limited thereto, and at least one of the first to fourth subpixels SP1, SP2, SP3, SP4 may have a shape and/or size different from that of other subpixels. A description of a structure of each of the plurality of subpixels SP will be described below with reference to FIGS. 3 and 4.

The display area DA may include a plurality of sub-pixels SP, as illustrated in FIG. 2, and each of the plurality of sub-pixels SP may include a light-emission area EA and a circuit area CA. In addition, as shown in FIG. 1, the display area DA may include a first line SL1 adjacent to each of the plurality of sub-pixels SP, and a second line SL2 arranged in a different direction from the first line SL1, for example, in the second direction (X-axis direction). The first line SL1 can be arranged in the first direction (Y-axis direction) as shown in FIG. 2. The first line SL1 and the second line SL2 according to one example are configured for receiving power and/or image signals from at least one of the gate driver GD and the pad portion PA and transmitting them to the plurality of sub-pixels SP of the display area DA. According to one example, the first line SL1 can be connected to a pixel power shorting bar VDD and/or a common power shorting bar VSS in a fourth non-display area NDA4.

The first line SL1 may include a plurality of first sub-lines SL1-1, SL1-2, SL1-3, SL1-4. Each of the plurality of first sub-lines SL1-1, SL1-2, SL1-3, SL1-4 may be any one of a pixel power line, a common power line, a reference line, and a data line. The plurality of first sub-lines SL1-1, SL1-2, SL1-3, SL1-4 may mean a group of signal lines connected to one sub-pixel SP.

The second line SL2 may be electrically connected to at least one of the plurality of first sub-lines and may be connected to each of the plurality of sub-pixels SP. Accordingly, each of the plurality of sub-pixels SP may receive power and/or image signals through the first line SL1 and the second line SL2 to output an integrated image. According to one example, a plurality of second lines SL2 may be provided. In this case, the second line SL2 may include a plurality of sub-lines connected to the first line SL1 and a gate line connected to a gate driver GD.

The non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be configured to surround the display area DA. That is, the non-display area NDA can be arranged to surround the display area DA.

The display apparatus 100 according to one embodiment of the present disclosure may have a pad portion PA placed in the non-display area NDA. The pad portion PA may supply power and/or a signal for the pixel P provided in the display area DA to output an image. The non-display area NDA can include a first non-display area NDA1, a second non-display area NDA2, a third non-display area NDA3, and a fourth non-display area NDA4.

According to one example, the pad portion PA may be placed in the first non-display area NDA1 located above the display area DA based on FIG. 1.

The gate driver GD supplies gate signals to the gate lines in accordance with the gate control signal input from the timing control portion 180. The gate driver GD may be formed on one side of the display area DA of the display panel or on the non-display area NDA outside both sides of the display area DA in a gate driver in panel GIP method as shown in FIG. 1.

A plurality of gate drivers GD may be separately disposed on a left side of the display area DA, that is, on the second non-display area NDA2 and a right side of the display area DA, that is, on the third non-display area NDA3.

The pixel power shorting bar VDD and the common power shorting bar VSS can be placed (or arranged) in the fourth non-display area NDA4 facing the pad portion PA based on (or relative to) the display area DA.

Referring to FIG. 3, the display area DA (or each of the plurality of sub-pixels SP) may include the light-emission area EA and the non-light emission area NEA. The light-emission area EA may be provided adjacent to the non-light emission area NEA.

The light emission area EA is the area where light is emitted by the organic light-emitting element layer E. The light emission area EA may correspond to an area in the pixel P that emits light. The non-light emission area NEA is an area that does not transmit most of the light incident from the outside.

For example, the non-light emission area NEA may be an area excluding the light emission area EA where light is emitted. In one example, the non-light emission area NEA may include a circuit area CA (shown in FIG. 4). The circuit area CA may include a thin film transistor 112 for driving each of the plurality of subpixels SP (or an organic light emitting element layer E of each of the plurality of subpixels SP).

The non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

Referring to FIG. 3, the display apparatus 100 according to one embodiment of the present disclosure may include a substrate 110, a first planarization layer 120, a second planarization layer 130, and a sloped reflective portion 140.

The first planarization layer 120 may be disposed on the substrate 110. The second planarization layer 130 may be disposed on the first planarization layer 120. According to one example, the second planarization layer 130 may have a different refractive index from the first planarization layer 120. For example, the second planarization layer 130 may be provided to have a higher refractive index than the first planarization layer 120. That is, a refractive index of the first planarization layer 120 may be provided to be smaller than a refractive index of the second planarization layer 130. This is to refract light at a boundary between the first planarization layer 120 and the second planarization layer 130.

The sloped reflective portion 140 is configured for reflecting light emitted from an organic light-emitting layer 116 toward an adjacent subpixel toward the substrate 110. Alternatively, the sloped reflective portion 140 is configured for reflecting light emitted from the organic light-emitting layer 116 that is wave-guided between a pixel electrode 114 (or a lower surface of the pixel electrode 114) and a reflective electrode 117 (or an upper surface of the reflective electrode 117) toward the substrate 110. According to one example, the sloped reflective portion 140 may be placed (or disposed) in the non-light emission area NEA (or the first non-light emission area NEA1) between the plurality of subpixels SP. The sloped reflective portion 140 may be placed (or disposed) on the second planarization layer 120. In the embodiment as shown in FIG. 3, since the sloped reflective portion 140 is a part of the reflective electrode 117 positioned in the non-light emission area NEA (or the first non-light emission area NEA1), it may be indicated by the drawing symbol 117′.

Meanwhile, in the display apparatus 100 according to one embodiment of the present disclosure, the first planarization layer 120 may include a first sloped portion 121 arranged obliquely (or at an angle). According to one example, the first sloped portion 121 can be formed by depositing a material forming the first planarization layer 120 on an entire surface of the substrate 110 so as to cover the color filter CF, and then partially removing the first planarization layer 120 by a patterning process (or an ashing process). Accordingly, the substrate 110 may include a patterned portion (or an outer patterned portion) formed concavely in the non-light emission area NEA (or the first non-light emission area NEA1) between the plurality of subpixels SP.

The first sloped portion 121 may be a single inclined surface forming the patterned portion. According to one example, a width of the patterned portion may be provided to become narrower in the direction from the opposing substrate 200 toward the substrate 110. Accordingly, the first sloped portion 121 can be arranged inclinedly between the color filter CF and the second planarization layer 130. For example, as shown in FIG. 3, the first sloped portion 121 may be positioned in the non-light emission area NEA (or the first non-light emission area NEA1) and may be positioned so as to be inclined in a direction toward the light emission area EA as it goes upward (or inclined in an upward direction from the substrate 110 toward the opposing substrate 200).

As shown in FIG. 3, in the display apparatus 100 according to one embodiment of the present disclosure, the first sloped portion 121 may partially overlap with the sloped reflective portion 140. For example, the first sloped portion 121 may partially overlap with the sloped reflective portion 140 in the third direction (Z-axis direction).

Since the display apparatus 100 according to one embodiment of the present disclosure is a bottom-emission type display apparatus, some of the light emitted from the organic light-emitting layer 116 may be reflected by the sloped reflective portion 140. Some of the light reflected by the sloped reflective portion 140 may form an optical path toward the substrate 110 (or in a frontal direction perpendicular to the upper surface of the substrate 110), and thus may reach the first sloped portion 121.

Since the second planarization layer 130 and the first planarization layer 120 have different refractive indices, light incident on the first planarization layer 120 can be refracted at the first sloped portion 121. Accordingly, the display apparatus 100 according to one embodiment of the present disclosure can improve a viewing angle because the light reflected by the sloped reflective portion 140 can be refracted in a direction other than a frontal direction (e.g., a vertical direction with respect to the upper surface of the substrate 110) at the first sloped portion 121.

A general bottom-emission display apparatus can emit light emitted from a light-emitting layer downward by using reflective electrodes arranged at an angle. However, if an angle of inclination of the reflective electrodes with respect to a ground is too small, color mixing between subpixels may occur. Therefore, the general bottom-emission display apparatus has limitations in improving a viewing angle.

In contrast, the display apparatus 100 according to one embodiment of the present disclosure is provided such that the first sloped portion 121 partially overlaps the sloped reflective portion 140, so that light can be refracted through the first sloped portion 121, thereby preventing color mixing and improving the viewing angle.

As described above, since the second planarization layer 130 is formed in a subsequent process than the first planarization layer 120, the first sloped portion 121 may be a boundary surface between the first planarization layer 120 and the second planarization layer 130.

Meanwhile, after the patterned portion having the first sloped portion 121 is provided in the non-light emission area NEA (or the first non-light emission area NEA1) on the substrate 110, the second planarization layer 130 may be formed. Accordingly, the second planarization layer 130 may partially include a second sloped portion 131 that is arranged to be inclined between the first sloped portion 121 and the sloped reflective portion 140. According to one example, the second sloped portion 131 may be provided at a same angle (for example, a same angle (e.g., acute angle) with respect to the upper surface of the substrate 110) as the first sloped portion 121, but is not limited thereto. The second sloped portion 131 can be provided at a different angle from the first sloped portion 121 by performing an additional patterning process (or an ashing process) after a material forming the second planarization layer 130 is applied on the first planarization layer 120.

Hereinafter, the structure of each of the plurality of subpixels SP will be specifically described with reference to FIG. 4.

FIG. 4 is a schematic cross-sectional view of the line II-II′ shown in FIG. 2.

Referring to FIG. 4, the display apparatus 100 according to one embodiment of the present disclosure can include a buffer layer BL, a plurality of inorganic films 111, a thin film transistor 112, a color filter CF, a first planarization layer 120, a second planarization layer 130, a pixel electrode 114, a bank 115, an organic light emitting layer 116, a reflective electrode 117, and an encapsulation layer 118.

Each of the plurality of subpixels SP according to one embodiment may include the plurality of inorganic films 111 provided on an upper surface of the buffer layer BL, including a gate insulating layer 111a, an interlayer insulating layer 111b, and a passivation layer 111c.

Also, each of the plurality of subpixels SP may include a color filter CF provided on the plurality of inorganic films 111, a first planarization layer 120 and a second planarization layer 130 provided on the color filter CF. The second planarization layer 130 may be placed on the first planarization layer 120. The pixel electrode 114 may be placed on the second planarization layer 130.

Each of the plurality of subpixels SP may further include a bank 115 covering one edge of the pixel electrode 114, an organic light-emitting layer 116 on the pixel electrode 114 and the bank 115, and a reflective electrode 117 on the organic light-emitting layer 116. The encapsulation layer 118 may be placed on the reflective electrode 117.

The thin film transistor 112 for driving of the subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, and the passivation layer 111c. The pixel electrode 114, the organic light emitting layer 116 and the reflective electrode 117 may be included in a light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in a pixel area may have a characteristic in which the threshold voltage is shifted by light. To prevent this, the display panel or the substrate 110 may further include a light-shielding layer (not shown) provided under an active layer of at least one of the thin film transistor 112, a first switching thin film transistor, and a second switching thin film transistor.

The light-shielding layer is provided between the substrate 110 and the active layer 112a to block light incident on the active layer 112a through the substrate 110, thereby minimizing changes in the threshold voltage of the transistor caused by external light. In addition, the light shielding layer may be provided between the substrate 110 and the active layer 112a to prevent the thin film transistor from being visible to the user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF may be placed on the passivation layer 111c. For example, the color filter CF may be placed between the plurality of inorganic films 111 and the first planarization layer 120. The color filter CF may include a red color filter CF1 arranged in the red subpixel SP1, a green color filter CF2 arranged in the green subpixel SP2, and a blue color filter (not shown) arranged in the blue subpixel SP3. Since the white subpixel SP4 is provided to emit white light, it may not include the color filter.

The first planarization layer 120 may be provided on the substrate 110 to cover the passivation layer 111c and the color filter CF. According to one example, the first planarization layer 120 may be placed between the substrate 110 and the pixel electrode 114. The first planarization layer 120 may be formed in the entire circuit area CA in which the thin film transistor 112 is disposed and the entire light emission area EA. In addition, the first planarization layer 120 may be formed in the remaining non-display area NDA except a pad area PA of the non-display area NDA and the entire display area DA. For example, the first planarization layer 120 may include an extension portion (or an enlarged portion) extended or enlarged from the display area DA to the remaining non-display area NDA except the pad area PA. Therefore, the first planarization layer 120 may have a size relatively wider than that of the display area DA.

The first planarization layer 120 according to one example may be formed to have a relatively thick thickness, thereby providing a flat surface on the display area DA and the non-display area NDA. For example, the first planarization layer 120 may be made of an organic material such as photo acryl, benzocyclobutene, polyimide and fluorine resin.

The second planarization layer 130 may be disposed on the substrate 110. For example, the second planarization layer 130 may be disposed on the first planarization layer 120. According to one example, the second planarization layer 130 may be disposed between the first planarization layer 120 and the pixel electrode 114. The second planarization layer 130 may be formed of a same material as the first planarization layer 120, but is not limited thereto. As described above, the second planarization layer 130 may be provided to have a different refractive index from the first planarization layer 120.

Referring to FIG. 4, an upper surface of the second planarization layer 130 can be provided flat. Accordingly, the pixel electrode 114 on the second planarization layer 130 can also be provided flat, and the organic light-emitting layer 116 and the reflective electrode 117 formed thereon can also be provided in a flat form. For example, the pixel electrode 114 may include a flat surface 114a disposed on an upper surface of the second planarization layer 130 that is provided flatly. The flat surface 114a of the pixel electrode 114 may be a lower surface of the pixel electrode 114. As shown in FIG. 3, the flat surface 114a of the pixel electrode 114 may be provided parallel to the second direction (X-axis direction).

Since the pixel electrode 114, the organic light-emitting layer 116, and the reflective electrode 117, i.e., the organic light-emitting element layer E, are provided flatly in the light-emission area EA, a thicknesses of the pixel electrode 114, the organic light-emitting layer 116, and the reflective electrode 117 can be formed uniformly within the light-emission area EA. Accordingly, the organic light-emitting layer 116 can emit light uniformly without deviation within the light-emission area EA.

The pixel electrode 114 may be formed on the second planarization layer 130. The pixel electrode 114 may be connected to the drain electrode or source electrode of the thin film transistor through a contact hole penetrating the first planarization layer 120 and the passivation layer 111c. The edge portions on both sides of the pixel electrode 114 may be covered by the bank 115. Since FIG. 4 is a cross-sectional view in the first direction (Y-axis direction), the bank 115 may be provided to cover each of an upper edge and a lower edge of the pixel electrode 114 based on a plane (e.g., FIG. 2). In contrast, as shown in FIG. 3, the bank 115 may not be arranged between the plurality of sub-pixels SP adjacent to each other in the second direction (X-axis direction). Accordingly, the display apparatus 100 according to one embodiment of the present disclosure may be configured as a bank-less structure in which the bank 115 is not arranged between the plurality of sub-pixels SP adjacent to each other in the second direction (X-axis direction).

The pixel electrode 114 may be made of at least one of a transparent metal material and a semi-transmissive metal material.

Because the display apparatus 100 according to an embodiment of the present disclosure is configured as the bottom emission type display apparatus, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and can be placed adjacent to the light emission area EA of each of the plurality of sub-pixels SP. For example, the bank 115 may be disposed in the non-light emission area NEA (or non-light emission area NEA on the upper or lower side of the pixel electrode 114). The bank 115 may be formed to cover a portion where the edge of the pixel electrode 114 is formed. Accordingly, the bank 115 may prevent contact of the pixel electrode 114 and the reflective electrode 117 at the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Thus, the bank 115 may be partially provided between the pixel electrode 114 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the reflective electrode 117. According to one example, the organic light emitting layer 116 may be disposed in the light emission area EA and the non-light emission area NEA. The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer (for example, the organic light emitting layer 116) may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), a blue emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), an electron transport layer (ETL) and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The reflective electrode 117 may be formed on the organic light-emitting layer 116. The reflective electrode 117 may be arranged in the non-display area NDA (or a part of the non-display area NDA) and the display area DA. In the display area DA, the reflective electrode 117 may be arranged in the light-emission area EA and the non-light emission area NEA. That is, the reflective electrode 117 may be provided to cover the entire display area DA. As a result, the reflective electrode 117 may be provided to have a size larger than the display area DA and smaller than the substrate 110, so that it may be arranged in the non-display area NDA (or a part of the non-display area NDA) and the display area DA.

The reflective electrode 117 according to one example may include a metal material. The reflective electrode 117 may reflect light emitted from the organic light-emitting layer 116 in the plurality of subpixels SP toward the lower surface of the substrate 110. Therefore, the display apparatus 100 according to an embodiment of the present disclosure may be implemented as a bottom emission type display apparatus.

The display apparatus 100 according to one embodiment of the present disclosure is a bottom emission type display apparatus and has to reflect light emitted from the light emitting layer 116 toward the substrate 110, and thus the reflective electrode 117 may be made of a metal material having high reflectance. According to one example, the reflective electrode 117 may be formed of a metal material having high reflectance such as a silver (Ag), an aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, an opposing electrode and a cathode electrode.

The encapsulation layer 118 is formed on the reflective electrode 117. The encapsulation layer 118 serves to prevent oxygen or moisture from penetrating into the organic light-emitting layer 116 and the reflective electrode 117. The encapsulation layer 118 may be provided with a plurality of layers including at least one inorganic film and at least one organic film. The encapsulation layer 118 may further contain an absorbent material for absorbing moisture or oxygen in order to enhance the moisture-prevention effect. For example, the absorbent material may be a getter.

Meanwhile, as shown in FIG. 3, the encapsulation layer 118 may be arranged not only in the light-emission area EA but also in the non-light emission area NEA. The encapsulation layer 118 may be arranged between the reflective electrode 117 and the opposing substrate 200.

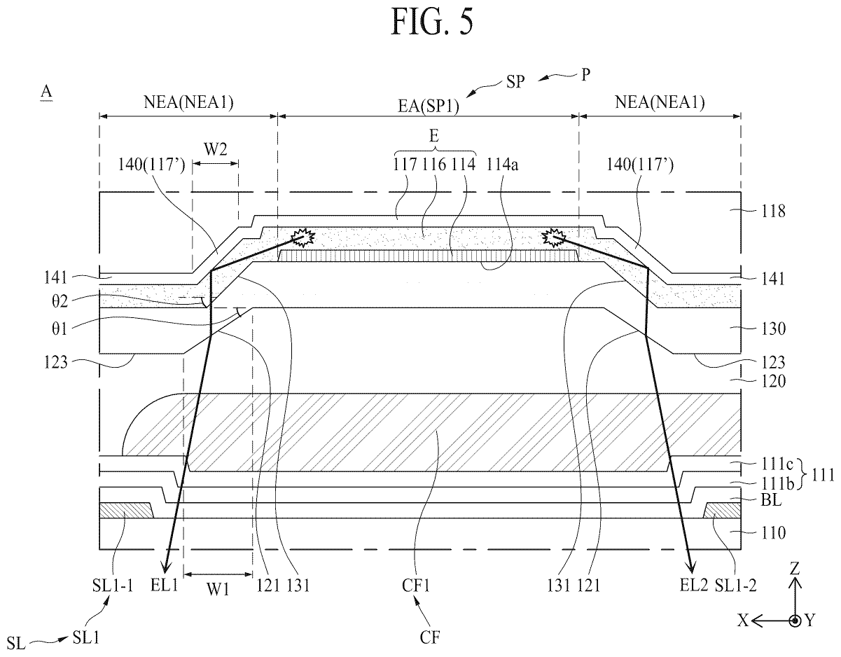

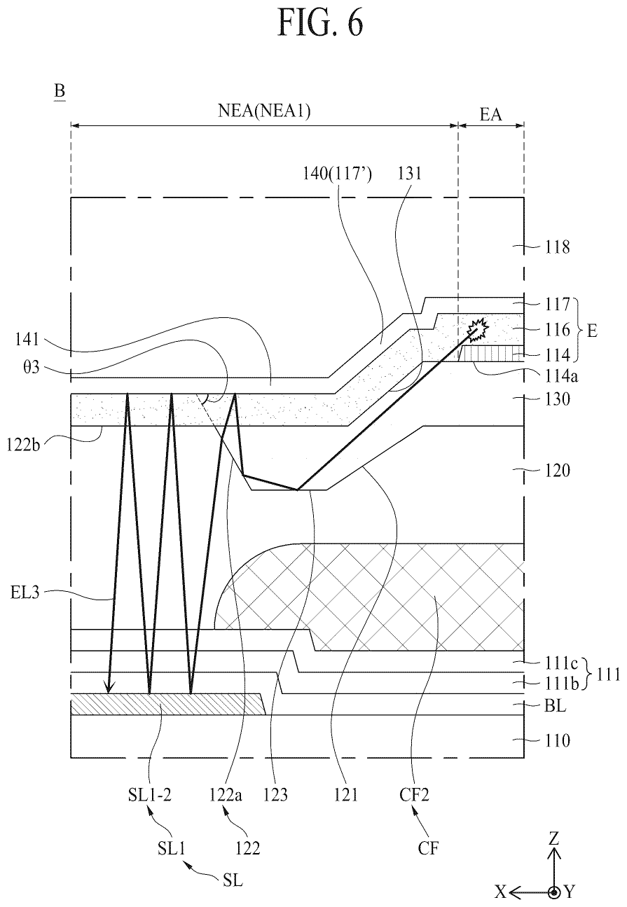

FIG. 5 is an enlarged view of a part A shown in FIG. 3, and FIG. 6 is an enlarged view of a part B shown in FIG. 3.

Referring to FIG. 5, in the display apparatus 100 according to one embodiment of the present disclosure, the first sloped portion 121 may be provided so as not to overlap with the light-emission area EA. As described above, the sloped reflective portion 140 may be provided so as to overlap with the first sloped portion 121. The first sloped portion 121 is configured for refracting light (e.g., frontal light) that is incident after being reflected by the sloped reflective portion 140. Frontal light may mean light whose light path is formed in a direction perpendicular to the upper surface of the substrate 110. Accordingly, when the first sloped portion 121 overlaps the light-emission area EA, the first sloped portion 121 and the sloped reflective portion 140 do not overlap in the third direction (Z-axis direction), so light (e.g., frontal light) reflected by the sloped reflective portion 140 cannot be refracted. Therefore, the display apparatus 100 according to one embodiment of the present disclosure is provided so that the first sloped portion 121 is spaced apart from the light-emission area EA by a predetermined distance so as not to overlap with the light-emission area EA, thereby refracting light that is incident after being reflected by the sloped reflective portion 140, thereby improving the viewing angle.

Referring to FIG. 5, light emitted from the organic light-emitting layer 116 and directed toward the sloped reflective portion 140 on a left side of the light-emission area EA is firstly reflected by the sloped reflective portion 140 (or a left sloped reflective portion 140) and the light path is converted to frontal light, after which it can reach the first sloped portion 121. Light reaching the first sloped portion 121 can be secondarily refracted due to a difference in refractive index between the first planarization layer 120 and the second planarization layer 130 and be emitted to an outside of the substrate 110. For example, based on FIG. 5, light reaching the first sloped portion 121 may be refracted to the left (in other words, in a leftward direction) and emitted to the outside of the substrate 110. In the present disclosure, light refracted to the left by the first sloped portion 121 may be defined as a first refracted light EL1. Therefore, a user on a left side based on the frontal direction can view the image by perceiving the first refracted light EL1.

Referring again to FIG. 5, among the light emitted from the organic light-emitting layer 116, light directed toward the sloped reflective portion 140 on a right side of the light-emission area EA is firstly reflected by the sloped reflective portion 140 (or a right sloped reflective portion 140) and the light path is converted to frontal light, after which it can reach the first sloped portion 121. Light reaching the first sloped portion 121 may be secondarily refracted due to the difference in refractive index between the first planarization layer 120 and the second planarization layer 130 and may be emitted to the outside of the substrate 110. For example, with reference to FIG. 5, light reaching the first sloped portion 121 may be refracted to the right (in other words, in a rightward direction) and may be emitted to the outside of the substrate 110. In the present disclosure, light refracted to the right by the first sloped portion 121 can be defined as a second refracted light EL2. Accordingly, a user on the right side based on the frontal direction can view the image by perceiving the second refracted light EL2.

Referring again to FIG. 5, a width W1 of the first sloped portion 121 may be equal to or greater than a width W2 of the sloped reflective portion 140. The sloped reflective portion 140 may reflect some of a light emitted from the organic light-emitting layer 116. Therefore, from the perspective of the first sloped portion 121, the sloped reflective portion 140 may function as a light source. The first sloped portion 121 may function as a lens since it refracts light incident from the sloped reflective portion 140. Therefore, if the width W1 of the first sloped portion 121 is narrower than the width W2 of the sloped reflective portion 140, some of the light reflected by the sloped reflective portion 140 having the function of a light source does not reach the first sloped portion 121, so the effect of improving the viewing angle may be minimal. However, the display apparatus 100 according to one embodiment of the present disclosure may have the width W1 of the first sloped portion 121 equal to or greater than the width W2 of the sloped reflective portion 140, thereby receiving all (or most) of the light incident from the sloped reflective portion 140, thereby improving the viewing angle.

Meanwhile, in the display apparatus 100 according to one embodiment of the present disclosure, a first angle θ1 between the first sloped portion 121 and the flat surface 114a of the pixel electrode 114 may be provided to satisfy the following mathematical expression (or equation 1).

$$θ 1 < {sin}^{- 1} ( n 1 / n 2 )$$

A n1 is the refractive index of the first planarization layer 120. A n2 is the refractive index of the second planarization layer 130.

If the first angle θ1 does not satisfy the equation 1, the light reflected by the sloped reflective portion 140 may be totally reflected by the first sloped portion 121, resulting in light loss.

Accordingly, the display apparatus 100 according to one embodiment of the present disclosure is provided such that the first angle θ1 between the first sloped portion 121 and the flat surface 114a of the pixel electrode 114 satisfies equation 1, thereby preventing light loss from occurring due to total reflection by the first sloped portion 121. The first angle θ1 according to one example may be an acute angle.

In FIG. 5, the first angle θ1 is represented as the angle between an extension line of the flat surface located at the uppermost side of the first planarization layer 120 and the first sloped portion 121. However, since the extension line of the flat surface located at the uppermost side of the first planarization layer 120 is arranged parallel to the flat surface 114a of the pixel electrode 114, the first angle θ1 can be defined as the angle between the first sloped portion 121 and the flat surface 114a of the pixel electrode 114.

In addition, in the display apparatus 100 according to one embodiment of the present disclosure, a second angle θ2 between the sloped reflective portion 140 and the flat surface 114a of the pixel electrode 114 may be provided to satisfy the following mathematical expression (or equation 2).

$$θ 2 \leq ( 180 - {sin}^{- 1} ( n 1 / n 2 ) ) / 2$$

A n1 is the refractive index of the first planarization layer 120. A n2 is the refractive index of the second planarization layer 130.

If the second angle θ2 does not satisfy the equation 2, the light reflected by the sloped reflective portion 140 may be emitted in the frontal direction by the first sloped portion 121, so the viewing angle may not be improved.

Accordingly, the display apparatus 100 according to one embodiment of the present disclosure is provided such that the second angle θ2 between the sloped reflective portion 140 and the flat surface 114a of the pixel electrode 114 satisfies equation 2, so that light can be refracted and emitted in a direction other than a frontal direction by the first sloped portion 121, thereby improving the viewing angle. The second angle θ2 according to one example may be an acute angle.

According to one embodiment of the present disclosure, the display apparatus 100 is provided such that the first sloped portion 121 and the sloped reflective portion 140 satisfy the equation 1 and the equation 2, so that some of the light emitted from the organic light-emitting layer 116 can be emitted in a direction other than the frontal direction by the sloped reflective portion 140 and the first sloped portion 121, thereby improving the viewing angle.

In addition, the display apparatus 100 according to one embodiment of the present disclosure is provided with the sloped reflective portion 140 that is inclinedly positioned in the non-light emission area NEA (or the first non-light emission area NEA1), so that light directed to an adjacent subpixel can be reflected by the sloped reflective portion 140 and emitted to the outside of the substrate 110, thereby improving light extraction efficiency.

In addition, since the display apparatus 100 according to one embodiment of the present disclosure can extract light even in the non-light emission area NEA (or the first non-light emission area NEA1) by the sloped reflective portion 140, the display apparatus can have the same light emission efficiency or can have improved light emission efficiency even at lower power compared to a display apparatus without a sloped reflective portion, so that the overall power consumption can be reduced.

Referring to FIG. 3 and FIG. 6, in a display apparatus 100 according to one embodiment of the present disclosure, the display apparatus 100 may further include a flat reflective portion 141 provided in a non-emitting area NEA (or a first non-emitting area NEA1) on the substrate 110. The first planarization layer 120 may further include a light path changing portion 122 and an outer flat portion 123. The light path changing portion 122 may include an outer sloped portion 122a. The outer flat portion 123 may connect the outer sloped portion 122a and the first sloped portion 121. The outer flat portion 123 according to one example may be arranged parallel to the upper surface of the substrate 110. The light path changing portion 122 may be connected to the outer sloped portion 122a (in other words, may include the outer sloped portion 122a) and may further include an upper surface 122b located at the uppermost side thereof.

According to one example, a flat reflective portion 141 may be provided flatly in the non-light emission area NEA (or the first non-light emission area NEA1) between the plurality of subpixels SP. The flat reflective portion 141 is configured for reflecting light that is totally reflected and incident at the boundary between the first planarization layer 120 and the second planarization layer 130 among the light emitted from the organic light-emitting layer 116. For example, as shown in FIG. 6, the flat reflective portion 141 can reflect light emitted from the organic light-emitting layer 116 that is firstly totally reflected at the outer flat portion 123 and secondarily totally reflected at the outer sloped portion 122a and then forms an optical path to the flat reflective portion 141. Light reflected by the flat reflective portion 141 can form an optical path to the first line SL1 (or the first sub-line SL1-2), as shown in FIG. 6. Light reaching the first line SL1 (or the first sub-line SL1-2) can be reflected by the first line SL1 (or the first sub-line SL1-2) and form an optical path to the flat reflective portion 141 again.

The optical path changing portion 122 according to one example is configured for guiding light to the flat reflective portion 141. The optical path changing portion 122 may partially overlap with the flat reflective portion 141. For example, the outer sloped portion 122a included in the light path changing portion 122 may overlap with the flat reflective portion 141 in the third direction (Z-axis direction). As shown in FIG. 6, an upper surface 122b located at the uppermost side of the light path changing portion 122 may be in direct contact with the organic light-emitting layer 116.

The outer sloped portion 122a according to one example may be arranged to face the first sloped portion 121. For example, the outer sloped portion 122a may be arranged to face the first sloped portion 121 with the outer flat portion 123 interposed therebetween. The outer sloped portion 122a may be provided to form an acute angle with the flat reflective portion 141 (or a lower surface of the flat reflective portion 141). Accordingly, the outer sloped portion 122a may be arranged at a different angle from the first sloped portion 121. For example, the first sloped portion 121 may be arranged at an obtuse angle with respect to the flat surface 114a of the pixel electrode 114, and the outer sloped portion 122a may be arranged at an acute angle with respect to the flat surface 114a of the pixel electrode 114. Therefore, the outer sloped portion 122a can be arranged at a different angle from the first sloped portion 121 so that the light incident thereon is totally reflected by the outer flat portion 123.

In the display apparatus 100 according to one embodiment of the present disclosure, a third angle θ3 between the flat reflective portion 141 and the outer sloped portion 122a may be provided to satisfy the following mathematical expression (or equation 3).

$$θ 3 \leq {sin}^{- 1} ( n 1 / n 2 )$$

A n1 is the refractive index of the first planarization layer 120. A n2 is the refractive index of the second planarization layer 130.

If a third angle θ3 does not satisfy the equation 3, light totally reflected at the outer flat portion 123 may not be totally reflected at the outer sloped portion 122a and may pass through the outer sloped portion 122a and be emitted to an adjacent subpixel SP, which may cause color mixing or light leakage.

Accordingly, the display apparatus 100 according to one embodiment of the present disclosure is provided such that the third angle θ3 between the flat reflective portion 141 and the outer sloped portion 122a satisfies equation 3, so that light totally reflected at the outer flat portion 123 can be totally reflected at the outer sloped portion 122a, thereby forming a large refraction angle and allowing light to be guided toward the flat reflective portion 141. The third angle θ3 according to one example may be an acute angle.

In the display apparatus 100 according to one embodiment of the present disclosure, the line SL may partially overlap with each of the outer sloped portion 122a and the flat reflective portion 141. For example, as shown in FIG. 6, the first sub-line SL1-2 provided in the non-light emission area NEA (or the first non-light emission area NEA1) may partially overlap with the outer sloped portion 122a and the flat reflective portion 141. Accordingly, the line SL (or the first sub-line SL1-2) and the flat reflective portion 141 provided in the non-emitting area NEA (or the first non-emitting area NEA1) can be arranged in parallel. Since the line SL (or the first sub-line SL1-2) and the flat reflective portion 141 are arranged in parallel in the non-light emission area NEA (or the first non-light emission area NEA1), light whose light path is formed by the flat reflective portion 141 can be reflected multiple times (or several times) between the flat reflective portion 141 and the line SL (or the first sub-line SL1-2). Through such multiple reflections, light can be absorbed by the flat reflective portion 141 and the line SL (or the first sub-line SL1-2), and as a result, the light can be extinguished. In the present disclosure, light that is reflected multiple times (or several times) and extinguished by the flat reflective portion 141 and the line SL (or the first sub-line SL1-2) can be defined as extinguished light EL3.

Therefore, the display apparatus 100 according to one embodiment of the present disclosure can change (or guide) the light path to the flat reflective portion 141 by totally reflecting the light directed toward the adjacent subpixel SP through the outer sloped portion 122a and the outer flat portion 123, and the light whose light path has been changed (or guided) to the flat reflective portion 141 can be reflected multiple times (or several times) between the flat reflective portion 141 and the line SL (or the first sub-line SL1-2) and then disappear. Therefore, the display apparatus 100 according to one embodiment of the present disclosure can prevent light leakage between the plurality of subpixels SP adjacently arranged.

As a result, the display apparatus 100 according to one embodiment of the present disclosure is provided such that the outer sloped portion 122a of the light path changing portion 122 satisfies the equation 3, so that light emitted from the organic light-emitting layer 116 toward an adjacent subpixel can be extinguished through multiple reflections between the flat reflective portion 141 and the line SL, thereby preventing light leakage.

Meanwhile, as described above, the line SL (e.g., the first sub-line SL1-2) may be arranged between the plurality of sub-pixels SP. Therefore, as shown in FIG. 3, the display apparatus 100 according to one embodiment of the present disclosure may have a structural feature in which the first color filter CF1 is arranged spaced apart from the second color filter CF2 on the line SL (e.g., the first sub-line SL1-2). In addition, light that is totally reflected by the outer flat portion 123 and the outer sloped portion 122a and is incident on the flat reflective portion 141 may be reflected multiple times and extinguished between the flat reflective portion 141 and the line SL (e.g., the first sub-line SL1-2). Accordingly, the display apparatus 100 according to one embodiment of the present disclosure may have a structural feature in which the line SL (e.g., the first sub-line SL1-2) does not overlap with the first sloped portion 121 (or the sloped reflective portion 140). In addition, since the display apparatus 100 according to one embodiment of the present disclosure must guide light to the flat reflective portion 141 through the outer slope portion 122a, it may have a structural feature in which the first planarization layer 120 (or the light path changing portion 122) is arranged between two adjacent subpixels (e.g., the first subpixel SP1 and the second subpixel SP2).

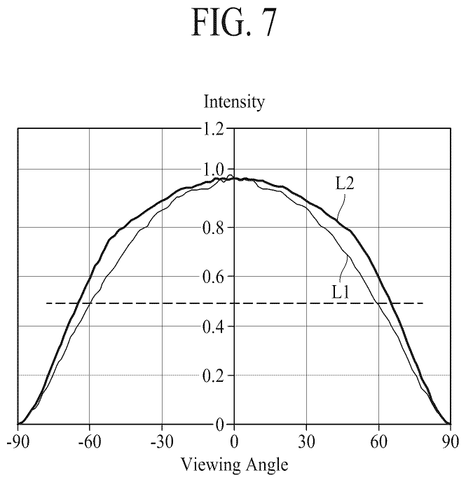

FIG. 7 is a graph showing the viewing angle of a display apparatus according to one embodiment of the present disclosure and the viewing angle of a display apparatus according to a comparative example.

Referring to FIG. 7, a horizontal axis represents a viewing angle and a vertical axis represents a light intensity. L1 is a graph showing a viewing angle as function of a light intensity of a display apparatus according to a comparative example without the first sloped portion 121. L2 is a graph showing a viewing angle as a function of a light intensity of a display apparatus 100 according to one embodiment of the present disclosure.

As shown in FIG. 7, it can be seen that the viewing angle of the display apparatus according to the comparative example has a viewing angle of about −58 to about +58 at a luminance half-value angle with a light intensity of 0.5. This is because the display apparatus according to the comparative example does not have a first sloped portion 121 like the present invention, so most of a light is emitted in a frontal direction. The luminance half-value angle may mean the angle at which the luminance becomes 50% when the luminance of the light emitted in the frontal direction is assumed to be 100%.

In contrast, it can be seen that the display apparatus 100 according to one embodiment of the present disclosure has a viewing angle of about −66 to about +66 at a luminance half-value angle with a light intensity of 0.5. This is because the display apparatus 100 according to one embodiment of the present disclosure is provided with the first sloped portion 121 that partially overlaps the sloped reflective portion 140 in the path through which light reflected by the sloped reflective portion 140 is emitted. Accordingly, the display apparatus 100 according to one embodiment of the present disclosure can have an improved viewing angle because the light reflected from the sloped reflective portion 140 can be refracted in a direction other than the frontal direction by the first sloped portion 121.

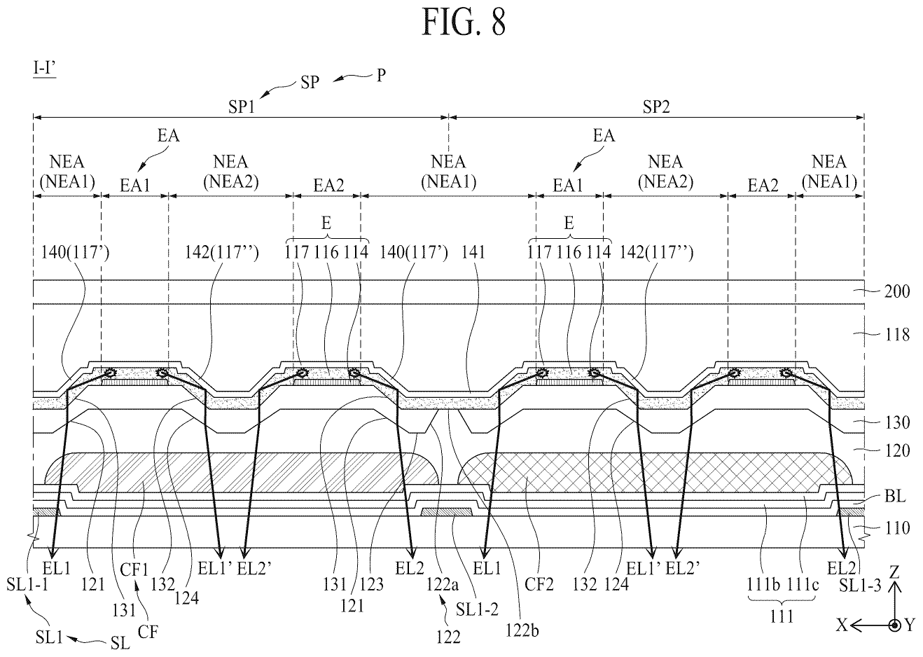

FIG. 8 is a schematic cross-sectional view of a display apparatus according to a second embodiment of the present disclosure, which is another example of FIG. 3.

Referring to FIG. 8, the display apparatus 100 according to a second embodiment of the present disclosure is the same as the display apparatus according to FIGS. 1 to 6 described above, except that the structures of the light-emission area EA, the first planarization layer 120, the second planarization layer 130, and the reflective electrode 117 are changed. Therefore, the same reference numerals are given to the same configurations, and only different configurations will be described below.

In the case of the display apparatus according to FIGS. 1 to 6, each of the plurality of subpixels SP includes one light-emission area EA, and the sloped reflective portion 140 and the first sloped portion 121 are arranged in the non-light emission area NEA (or the first non-light emission area NEA1) provided between the plurality of subpixels SP (or between the light-emission areas EA of each of the plurality of subpixels SP. Accordingly, in the case of the display apparatus according to FIGS. 1 to 6, the light path can be changed to a direction other than the frontal direction by the sloped reflective portion 140 and the first sloped portion 121 on an outside of each of the plurality of subpixels SP (or on an outside of the light-emission area EA of each of the plurality of subpixels SP, so that the viewing angle can be improved.

In contrast, in the case of the display apparatus according to FIG. 8, each of the light-emission areas EA of the plurality of subpixels SP may include a first light-emission area EA1 and a second light-emission area EA2. For example, the first subpixel SP1 of the display apparatus according to FIG. 8 may include the first light-emission area EA1 and the second light-emission area EA2 that are spaced apart from each other. The non-light emission area NEA (or second non-light emission area NEA2) may be provided between the first light-emission area EA1 and the second light-emission area EA2. As shown in FIG. 8, since the pixel electrode 114 is not arranged between the first light-emission area EA1 and the second light-emission area EA2, light is not emitted between the first light-emission area EA1 and the second light-emission area EA2.

Meanwhile, as shown in FIG. 8, the first planarization layer 120 may include a first inner sloped portion 124 that is arranged at an angle (in other words, obliquely) between the first light-emission area EA1 and the second light-emission area EA2. According to one example, the first inner sloped portion 124 can be formed by depositing a material forming the first planarization layer 120 on the entire surface of the substrate 110 so as to cover the color filter CF, and then partially removing the first planarization layer 120 by a patterning process (or an ashing process). Accordingly, the substrate 110 may include a patterned portion (or an inner patterned portion) formed concavely in the non-light emission area NEA (or second non-light emission area NEA2) between the first light-emission area EA1 and the second light-emission area EA2. According to one example, the inner patterned portion may be formed together with an outer patterned portion in the first non-light emission area NEAL.

The first inner sloped portion 124 may be a single inclined surface forming the patterned portion (or the inner patterned portion). According to one example, a width of the inner patterned portion may be provided to become narrower in the direction from the opposing substrate 200 toward the substrate 110. Accordingly, the first inner sloped portion 124 may be arranged to be inclined between the color filter CF and the second planarization layer 130. For example, as shown in FIG. 8, the first inner sloped portion 124 is formed in the non-light emission area NEA (or second non-light emission area NEA2) provided on an inner side of one subpixel SP, and may be arranged to be inclined in a direction toward the first light-emission area EA1 (or second light-emission area EA2) as it goes upward.

The second planarization layer 130 may include a second inner sloped portion 132 that partially overlaps the first inner sloped portion 124. Since the second inner sloped portion 132 is formed in a subsequent process after the first inner sloped portion 124 is formed, it may be formed to be inclined along the profile of the first inner sloped portion 124. The second inner sloped portion 132 may be provided at the same inclination angle as the first inner sloped portion 124, but is not limited thereto.

Referring to FIG. 8, each of the plurality of subpixels SP may include an inner sloped reflective portion 142 disposed on the second inner sloped portion 132 (in other words, disposed over the second inner sloped portion 132). The inner sloped reflective portion 142 is configured for reflecting light emitted from the organic light-emitting layer 116 and wave-guided toward a center of the subpixel SP toward the substrate 110. According to one example, the inner sloped reflective portion 142 may be arranged in the non-light emission area NEA (or the second non-light emission area NEA2) provided on the inner side of each of the plurality of subpixels SP. Since the inner sloped reflective portion 142 is a part of the reflective electrode 117 arranged in the non-light emission area NEA (or the second non-light emission area NEA2), it may be indicated by a drawing symbol of 117″.

As shown in FIG. 8, in the display apparatus 100 according to the second embodiment of the present disclosure, the first inner sloped portion 124 may partially overlap with the inner sloped reflective portion 142. For example, the first inner sloped portion 124 may partially overlap with the inner sloped reflective portion 142 in the third direction (Z-axis direction).

Since the display apparatus 100 according to the second embodiment of the present disclosure is a bottom-emission type display apparatus, some of the light emitted from the organic light-emitting layer 116 may be reflected by the inner sloped reflective portion 142. The light reflected by the inner sloped reflective portion 142 may form an optical path toward the substrate 110 (or in a frontal direction perpendicular to the upper surface of the substrate 110), and thus may reach the first inner sloped portion 124.

Since the second planarization layer 130 and the first planarization layer 120 have different refractive indices, light incident on the first planarization layer 120 can be refracted at the first inner sloped portion 124. Accordingly, in the display apparatus 100 according to the second embodiment of the present disclosure, light reflected by the inner sloped reflective portion 142 can be refracted in a direction other than the frontal direction (e.g., a direction perpendicular to the upper surface of the substrate 110) at the first inner sloped portion 124, so that the viewing angle can be improved.

As a result, the display apparatus 100 according to the second embodiment of the present disclosure can emit light in a direction other than the frontal direction through the sloped reflective portion 140 and the first sloped portion 121 provided on an outer side of each of the plurality of subpixels SP, so that the viewing angle can be improved. In addition, the display apparatus 100 according to the second embodiment of the present disclosure can emit light in a direction other than the frontal direction through the inner sloped reflective portion 142 and the first inner sloped portion 124 provided on an inner side of each of the plurality of subpixels SP, so that the viewing angle can be maximized. Since the sloped reflective portion 140 is provided on the outer side of each of the plurality of subpixels SP, it can be expressed in terms of an outer sloped reflective portion 140.

In the present disclosure, light refracted in a right direction by the first inner sloped portion 124 based on FIG. 8 can be defined as first inner refracted light EL1′, and light refracted in a left direction by the first inner sloped portion 124 can be defined as second inner refracted light EL2′.

Meanwhile, referring to FIG. 8, the first inner sloped portion 124 may be positioned to be further away from the first sloped portion 121 in a direction (or downward direction) toward the substrate 110 from the sloped reflective portion 140 based on the first light-emission area EAL. Accordingly, the first planarization layer 120 positioned below the pixel electrode 114 of the first light-emission area EA1 may be provided in a trapezoidal shape including the first inner sloped portion 124 and the first sloped portion 121. Additionally, the first planarization layer 120 positioned below the pixel electrode 114 of the second light-emission area EA2 may also be provided in a trapezoidal shape including the first inner sloped portion 124 and the first sloped portion 121.

Therefore, the display apparatus 100 according to the second embodiment of the present disclosure can refract light through the first inner sloped portion 124 and the first sloped portion 121 arranged at different inclination angles on both sides of the first light-emission area EA1 and the second light-emission area EA2 of one subpixel SP, so that the viewing angle improvement can be maximized.

Meanwhile, the display apparatus 100 according to the second embodiment of the present disclosure is provided with the first sloped portion 121 and the outer sloped portion 122a in the first non-light emission area NEA1 of one sub-pixel SP (e.g., the first sub-pixel SP1), and the first inner sloped portion 124 in a second non-light emission area NEA2 of one sub-pixel SP (e.g., the first sub-pixel SP1), so that the color filter CF included in one sub-pixel SP (e.g., the first sub-pixel SP1) may have a structural feature that overlaps with the first sloped portion 121, the first inner sloped portion 124, and the outer sloped portion 122a.

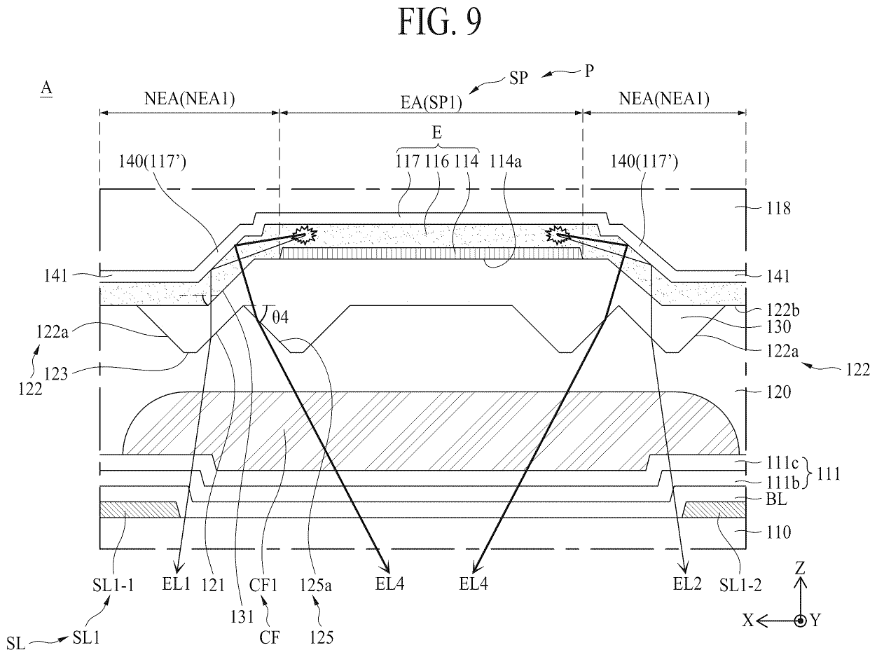

FIG. 9 is a schematic cross-sectional view of a display apparatus according to a third embodiment of the present disclosure, which is another example of FIG. 5.

Referring to FIG. 9, the display apparatus 100 according to a third embodiment of the present disclosure is the same as the display apparatus according to FIGS. 1 to 6, except that the structure of the first planarization layer 120 is changed. Therefore, the same reference numerals are given to the same configurations, and only different configurations will be described below.

In the case of the display apparatus according to FIGS. 1 to 6, the sloped reflective portion 140 and the first sloped portion 121 are arranged in the non-light emission area NEA (or the first non-light emission area NEA1) provided between the plurality of sub-pixels SP (or between the light-emission areas EA of the plurality of sub-pixels SP). Accordingly, in the case of the display apparatus according to FIGS. 1 to 6, the light path can be changed to a direction other than the frontal direction by the sloped reflective portion 140 and the first sloped portion 121 on the outside of each of the plurality of subpixels SP (or on the outside of the light-emission area EA of each of the plurality of subpixels SP, so that the viewing angle can be improved.

In contrast, in the case of the display apparatus according to FIG. 9, the first planarization layer 120 may further include a concave portion 125. According to one example, the concave portion 125 may be formed together with the outer patterned portion, but is not limited thereto. The concave portion 125 may be formed concavely between the first sloped portion 121 and a center of the light-emission area EA. Here, the center of the light-emission area EA may mean a center part of the pixel electrode 114 based on FIG. 9. According to one example, the concave portion 125 may include an auxiliary sloped portion 125a connected to the first sloped portion 121. The auxiliary sloped portion 125a may be one inclined surface forming the concave portion 125.

Meanwhile, a width of the concave portion 125 may be provided to become narrower in a direction from the opposing substrate 200 toward the substrate 110. Accordingly, the auxiliary sloped portion 125a may be arranged to be inclined between the color filter CF and the second planarization layer 130. For example, as shown in FIG. 9, the auxiliary sloped portion 125a may partially overlap the non-light emission area NEA (or the first non-light emission area NEA1) and the light emission area EA. In addition, with reference to FIG. 9, the auxiliary sloped portions 125a provided on each side of the light-emission area EA may be arranged closer to each other as they go downward. That is, with reference to FIG. 9, the auxiliary sloped portions 125a provided on each side of the light-emission area EA may be arranged to be inclined toward each other as they go downward.

As shown in FIG. 9, in the display apparatus 100 according to the third embodiment of the present disclosure, the auxiliary sloped portion 125a may be connected to the first sloped portion 121. For example, one side of the auxiliary sloped portion 125a may be connected to an end located at the uppermost side of the first sloped portion 121. The other side of the auxiliary sloped portion 125a can be connected to a bottom surface. The bottom surface is provided on the same line as the outer flat portion 123 and can be a flat surface. Accordingly, as shown in FIG. 9, the auxiliary sloped portion 125a can partially overlap with the pixel electrode 114.

Since the display apparatus 100 according to the third embodiment of the present disclosure is a bottom-emission type display apparatus, some of the light emitted from the organic light-emitting layer 116 may be reflected by the sloped reflective portion 140. Some of the light reflected by the sloped reflective portion 140 may form an optical path toward an inside (or center) of each of the plurality of subpixels SP. For example, some of the light reflected by the sloped reflective portion 140 may form an optical path toward the auxiliary sloped portion 125a.

Since the second planarization layer 130 and the first planarization layer 120 have different refractive indices, light incident on the first planarization layer 120 can be refracted at the auxiliary sloped portion 125a. Accordingly, the display apparatus 100 according to the third embodiment of the present disclosure can improve a viewing angle because the light reflected by the sloped reflective portion 140 can be refracted in a direction (e.g., a direction toward the center of the light-emission area EA) other than a frontal direction (e.g., a direction perpendicular to the upper surface of the substrate 110) at the auxiliary sloped portion 125a. In the present disclosure, the light refracted by the auxiliary slope 125a can be defined as a fourth refracted light EL4.

Meanwhile, in the display apparatus 100 according to the third embodiment of the present disclosure, a fourth angle θ4 between the auxiliary sloped portion 125a and the flat surface 114a of the pixel electrode 114 may be provided to satisfy the following mathematical expression (or equation 4).

$$θ4 < {sin}^{- 1} ( n 1 / n 2 )$$

A n1 is the refractive index of the first planarization layer 120. A n2 is the refractive index of the second planarization layer 130.

If the fourth angle θ4 does not satisfy the equation 4, the light reflected by the sloped reflective portion 140 may be totally reflected by the auxiliary sloped portion 125a and emitted to an adjacent subpixel, causing color mixing or disappearance.

Accordingly, the display apparatus 100 according to the third embodiment of the present disclosure is provided such that the fourth angle θ4 between the auxiliary sloped portion 125a and the flat surface 114a of the pixel electrode 114 satisfies the equation 4, thereby preventing light loss due to total reflection by the auxiliary sloped portion 125a from occurring. The fourth angle θ4 according to one example may be an acute angle.

As a result, the display apparatus 100 according to the third embodiment of the present disclosure can ensure a wide viewing angle because some of the light reflected by the sloped reflective portion 140 can be refracted in a direction other than the frontal direction by the first sloped portion 121 and emitted as the first refracted light EL1, and another some of the light reflected by the sloped reflective portion 140 can be refracted in a direction other than the frontal direction by the auxiliary sloped portion 125a and emitted as the fourth refracted light EL4.

Embodiments of the present disclosure have been described in more detail with reference to the accompanying drawings, but the present disclosure is not necessarily limited to these embodiments and may be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of the present disclosure shall be construed by the claims, and all technical ideas within the scope of the claims shall be construed to be included within the scope of the claims.

The present disclosure provides that a sloped portion (or the first sloped portion) of the first planarization layer partially overlaps with a reflective portion (or the sloped reflective portion) that is inclinedly arranged on the second planarization layer, so that light reflected by the reflective portion (or the sloped reflective portion) can be refracted in a direction other than the frontal direction at the sloped portion (or the first sloped portion) of the first planarization layer, thereby improving the viewing angle.

Furthermore, the display apparatus according to the present disclosure is provided with a sloped reflective portion that is inclinedly arranged in a non-light emission area, so that light directed toward an adjacent subpixel can be reflected by the sloped reflective portion and emitted to an outside of the substrate, thereby improving light extraction efficiency.

Furthermore, since the display apparatus according to the present disclosure can achieve light extraction even in a non-light emission area by a sloped reflective portion, it can have the same luminous efficiency as or improved luminous efficiency than that of a display apparatus without a sloped reflective portion even with low power consumption, so that the overall power consumption can be reduced.

The effects that may be obtained from the present disclosure are not limited to those mentioned above, and other effects not mentioned will be apparent to one having ordinary skill in the art from the following description.

What is claimed is:

1. A display apparatus comprising:
a substrate on which a plurality of subpixels are arranged;
a first planarization layer disposed on the substrate;
a second planarization layer disposed on the first planarization layer and having a different refractive index from the first planarization layer; and
a sloped reflective portion disposed on the second planarization layer and arranged obliquely in a non-light emission area between the plurality of subpixels, the sloped reflective portion configured to reflect light emitted from a light emission area of one of the plurality of subpixels toward an adjacent subpixel toward the substrate,
wherein the first planarization layer includes a first sloped portion arranged obliquely, and
wherein the first sloped portion partially overlaps the sloped reflective portion.

2. The display apparatus of claim 1, wherein the first sloped portion is a boundary surface between the first planarization layer and the second planarization layer.

3. The display apparatus of claim 1, wherein each of the plurality of subpixels includes a light-emission area adjacent to the non-light emission area, and the first sloped portion does not overlap with the light-emission area.

4. The display apparatus of claim 1, wherein a width of the first sloped portion is equal to or greater than a width of the sloped reflective portion.

5. The display apparatus of claim 1, wherein a refractive index of the first planarization layer is smaller than a refractive index of the second planarization layer.

6. The display apparatus of claim 1, wherein the second planarization layer includes a second sloped portion that is partially arranged inclinedly between the first sloped portion and the sloped reflective portion.

7. The display apparatus of claim 1, wherein each of the plurality of subpixels comprises:
a pixel electrode disposed on the second planarization layer;
an organic light-emitting layer on the pixel electrode; and
a reflective electrode on the organic light-emitting layer,
wherein the sloped reflective portion is a part of the reflective electrode.

8. The display apparatus of claim 7, wherein a first angle θ1 between the first sloped portion and a flat surface of the pixel electrode satisfies a mathematical expression below,
$$θ1 < {sin}^{- 1} ( n 1 / n 2 )$$
where a n1 is a refractive index of the first planarization layer, and a n2 is a refractive index of the second planarization layer.

9. The display apparatus of claim 7, wherein a second angle θ2 between the sloped reflective portion and a flat surface of the pixel electrode satisfies a mathematical expression below,
$$θ 2 \leq ( 180 - {sin}^{- 1} ( n 1 / n 2 ) ) / 2$$
where a n1 is a refractive index of the first planarization layer, and a n2 is a refractive index of the second planarization layer.

10. The display apparatus of claim 1, further comprising a flat reflective portion provided in the non-light emission area on the substrate,
wherein the first planarization layer further includes an optical path changing portion partially overlapping the flat reflective portion, and
wherein the optical path changing portion includes an outer sloped portion facing the first sloped portion and forming an acute angle with the flat reflective portion.

11. The display apparatus of claim 10, wherein the first planarization layer further includes an outer flat portion connecting the outer sloped portion and the first sloped portion.

12. The display apparatus of claim 10, wherein a third angle θ3 between the flat reflective portion and the outer sloped portion satisfies a mathematical expression below,
$$θ3 \leq {sin}^{- 1} ( n 1 / n 2 )$$
where a n1 is a refractive index of the first planarization layer, and a n2 is a refractive index of the second planarization layer.

13. The display apparatus of claim 10,
wherein the substrate includes a line arranged between the plurality of subpixels, and the line partially overlaps each of the outer sloped portion and the flat reflective portion.

14. The display apparatus of claim 13, wherein the plurality of subpixels include a first subpixel and a second subpixel adjacent to each other,
wherein the first subpixel includes a first color filter,
wherein the second subpixel includes a second color filter of a different color from the first color filter, and
wherein the first color filter is spaced apart from the second color filter on the line.

15. The display apparatus of claim 13, wherein each of the plurality of subpixels includes a light-emission area adjacent to the non-light emission area,
wherein the light-emission area of each of the plurality of subpixels includes a first light emission area and a second light emission area that are spaced apart from each other,
wherein the first planarization layer includes a first inner sloped portion arranged obliquely between the first light emission area and the second light emission area,
wherein the second planarization layer includes a second inner sloped portion that partially overlaps the first inner sloped portion,
wherein each of the plurality of subpixels includes an inner sloped reflective portion arranged on the second inner sloped portion.

16. The display apparatus of claim 15, wherein the first inner sloped portion is arranged to be further away from the first sloped portion in a direction toward the substrate from the sloped reflective portion based on the first light-emission area.

17. The display apparatus of claim 15, wherein at least one subpixel of the plurality of subpixels includes a color filter, and the color filter of the at least one subpixel overlaps the first sloped portion, the first inner sloped portion, and the outer sloped portion.

18. The display apparatus of claim 3, wherein the first planarization layer includes a concave portion formed concavely between the first sloped portion and a center of the light-emission area, and the concave portion includes an auxiliary sloped portion connected to the first sloped portion.

19. The display apparatus of claim 18, wherein each of the plurality of subpixels includes a pixel electrode arranged on the second planarization layer, and a fourth angle θ4 between the auxiliary sloped portion and a flat surface of the pixel electrode satisfies a mathematical expression below,
$$θ4 < {sin}^{- 1} ( n 1 / n 2 )$$
wherein a n1 is a refractive index of the first planarization layer, and a n2 is a refractive index of the second planarization layer.

20. The display apparatus of claim 18, wherein the auxiliary sloped portion partially overlaps the pixel electrode.
